(19) United States
(12) Patent Application Publication
(10) Pub. No.: US 2025/0255188 A1
(43) Pub. Date: Aug. 7, 2025

(54) PIEZOELECTRIC THIN FILM, AND PIEZOELECTRIC THIN FILM DEVICE

(71) Applicant: TDK Corporation, Chuo-ku, Tokyo (JP)

(72) Inventors: Chika KUNUGI, Chuo-ku, Tokyo (JP); Yukari INOUE, Chuo-ku, Tokyo (JP); Kenta ISHII, Chuo-ku, Tokyo (JP); Kazunari HIIRO, Chuo-ku, Tokyo (JP)

(73) Assignee: TDK Corporation, Chuo-ku, Tokyo (JP)

(21) Appl. No.: 18/605,387

(22) Filed: Mar. 14, 2024

(30) Foreign Application Priority Data
Mar. 20, 2023 (JP) 2023-044420
Dec. 18, 2023 (JP) 2023-213188

(51) Int. Cl. H10N 30/853; H10N 30/00

(52) U.S. Cl. CPC H10N 30/853; H10N 30/704

(57) ABSTRACT

Provided is a piezoelectric thin film having a first main surface and a second main surface located on a rear side of the first main surface. The piezoelectric thin film contains crystalline aluminum nitride having a wurtzite structure. The aluminum nitride contains a divalent element and a tetravalent element. Alternatively, the aluminum nitride contains a trivalent element. A developed interfacial area ratio of the second main surface is from 0.001 to 0.100.

### CROSS-REFERENCE TO RELATED APPLICATIONS

This application is based upon and claims the benefit of priority from Japanese Patent Application No. 2023-213188, filed on Dec. 18, 2023, and Japanese Patent Application No. 2023-044420, filed on Mar. 20, 2023, the entire contents of which are incorporated herein by reference.

### BACKGROUND

### Field

The present disclosure relates to a piezoelectric thin film and a piezoelectric thin film device.

### Description of the Related Art

Aluminum nitride (AlN) is a piezoelectric material having a wurtzite structure. A piezoelectric strain constant d of AlN is smaller than d of piezoelectric materials having a perovskite structure (for example, lead zirconate titanate) in the related art, but a piezoelectric output coefficient g of AlN is larger than g of the piezoelectric materials in the related art. In addition, AlN is a relatively inexpensive material. For these reasons, AlN has attracted attention in recent years. For example, Japanese Unexamined Patent Publication No. 2013-219743 discloses AlN in which a part of Al is substituted with additive elements such as a divalent element and a tetravalent element in order to improve piezoelectric properties. For example, Japanese Unexamined Patent Publication No. 2020-77788 discloses AlN in which a part of Al is substituted with a Group 3 element or a Group 13 element.

### SUMMARY

In general, a piezoelectric device (piezoelectric thin film device) using a thin film (piezoelectric thin film) having piezoelectric property includes an electrode layer formed directly on a surface of the piezoelectric thin film. However, the electrode layer is likely to be peeled off from the surface of the piezoelectric thin film consisting of AlN in the related art.

An object of an aspect of the present disclosure is to provide a piezoelectric thin film suppressing peeling-off of an electrode layer from a surface of the piezoelectric thin film, and a piezoelectric thin film device including the piezoelectric thin film.

For example, an aspect of the present disclosure relates to a piezoelectric thin film described in any one of the following [1] to [6], and a piezoelectric thin film device described in the following [7].
[1] A piezoelectric thin film having a first main surface, and a second main surface located on a rear side of the first main surface,
wherein the piezoelectric thin film contains crystalline aluminum nitride having a wurtzite structure,
wherein the aluminum nitride contains a divalent element and a tetravalent element, or the aluminum nitride contains a trivalent element, and
a developed interfacial area ratio of the second main surface is from 0.001 to 0.100.
[2] The piezoelectric thin film according to [1], further containing:
a plurality of first crystal grains and a plurality of second crystal grains,
wherein both the first crystal grains and the second crystal grains contain the aluminum nitride,
a (0001) plane of the aluminum nitride in the first crystal grains is parallel to the first main surface,
a (0001) plane of the aluminum nitride in the second crystal grains is inclined to the (0001) plane of the aluminum nitride in the first crystal grains, and
the plurality of second crystal grains are exposed on the second main surface.
[3] A piezoelectric thin film having a first main surface, and a second main surface located on a rear side of the first main surface,
wherein the piezoelectric thin film contains a plurality of first crystal grains and a plurality of second crystal grains,
both the first crystal grains and the second crystal grains contain crystalline aluminum nitride having a wurtzite structure,
a (0001) plane of the aluminum nitride in the first crystal grains is parallel to the first main surface,
a (0001) plane of the aluminum nitride in the second crystal grains is inclined to the (0001) plane of the aluminum nitride in the first crystal grains,
the plurality of second crystal grains are exposed on the second main surface, and
a developed interfacial area ratio of the second main surface is from 0.001 to 0.100.
[4] The piezoelectric thin film according to [2] or [3],
wherein an angle between the (0001) plane of the aluminum nitride in the first crystal grains and the (0001) plane of the aluminum nitride in the second crystal grains is from 0.1° to 30°.
[5] The piezoelectric thin film according to any one of [2] to [4],
wherein a secondary electron image of the second main surface is taken by a scanning electron microscope,
the secondary electron image is parallel to the first main surface, and
a ratio of a total area of the plurality of second crystal grains in the secondary electron image is from 0.01% to 20%.
[6] The piezoelectric thin film according to any one of [2] to [5],
wherein a secondary electron image of the second main surface is taken by a scanning electron microscope,
the secondary electron image is parallel to the first main surface, and
a Heywood diameter of the second crystal grains which is measured on the secondary electron image is from 5 nm to 2000 nm.
[7] A piezoelectric thin film device, including:
the piezoelectric thin film according to any one of [1] to [6];
a first electrode layer; and
a second electrode layer,
wherein the first main surface is directly stacked on the first electrode layer, and
the second electrode layer is directly stacked on the second main surface.

According to an aspect of the present disclosure, there are provided a piezoelectric thin film suppressing peeling-off of an electrode layer from a surface of the piezoelectric thin film, and a piezoelectric thin film device including the piezoelectric thin film.

### BRIEF DESCRIPTION OF THE DRAWINGS

FIG. 1 is a schematic exploded perspective view of a piezoelectric thin film device according to an embodiment of the present disclosure.

FIG. 2 shows a schematic cross-section of the piezoelectric thin film device shown in FIG. 1, and the cross-section shown in FIG. 2 is orthogonal to a first main surface of the piezoelectric thin film.

FIG. 3 is a schematic view showing a direction of a (0001) plane of aluminum nitride in first crystal grains contained in the cross-section shown in FIG. 2, a direction of a (0001) plane of aluminum nitride in second crystal grains contained in the cross-section shown in FIG. 2, and a direction of the first main surface of the piezoelectric thin film shown in FIG. 2.

FIG. 4 is a schematic view of an electron diffraction pattern containing a diffraction spot derived from a lattice plane of the aluminum nitride in the first crystal grains contained in the cross-section shown in FIG. 2, and a diffraction spot derived from a lattice plane of the aluminum nitride in the second crystal grains contained in the cross-section shown in FIG. 2.

FIG. 5 is a perspective view of a unit cell constituting a crystal structure (wurtzite structure) of the aluminum nitride contained in the piezoelectric thin film according to the embodiment of the present disclosure.

FIG. 6A is a perspective view of a unit cell showing a (0001) plane of the aluminum nitride, FIG. 6B is a perspective view of a unit cell showing a (0002) plane of the aluminum nitride, and FIG. 6C is a perspective view of a unit cell showing a (10−10) plane of the aluminum nitride.

FIG. 7A is a secondary electron image of a part of a second main surface of a piezoelectric thin film of Example 7, the secondary electron image shown in FIG. 7A is parallel to a first main surface, and FIG. 7B is a monochrome image obtained by image processing (binarization processing) of the secondary electron image shown in FIG. 7A.

FIG. 8 is an image of a cross-section of the piezoelectric thin film of Example 7, and the cross-section shown in FIG. 8 is orthogonal to the first main surface of the piezoelectric thin film.

FIG. 9A is an electron diffraction pattern measured by causing an electron beam to be incident to Measurement Point 1 in the cross-section shown in FIG. 8, and FIG. 9B is an electron diffraction pattern measured by causing an electron beam to be incident to Measurement Point 2 in the cross-section shown in FIG. 8.

FIG. 10A is an electron diffraction pattern measured by causing an electron beam to be incident to Measurement Point 3 in the cross-section shown in FIG. 8, and FIG. 10B is an electron diffraction pattern measured by causing an electron beam to be incident to Measurement Point 4 in the cross-section shown in FIG. 8.

FIG. 11A is an electron diffraction pattern measured by causing an electron beam to be incident to Measurement Point 5 in the cross-section shown in FIG. 8, and FIG. 11B is an electron diffraction pattern measured by causing an electron beam to be incident to Measurement Point 6 in the cross-section shown in FIG. 8.

### DETAILED DESCRIPTION

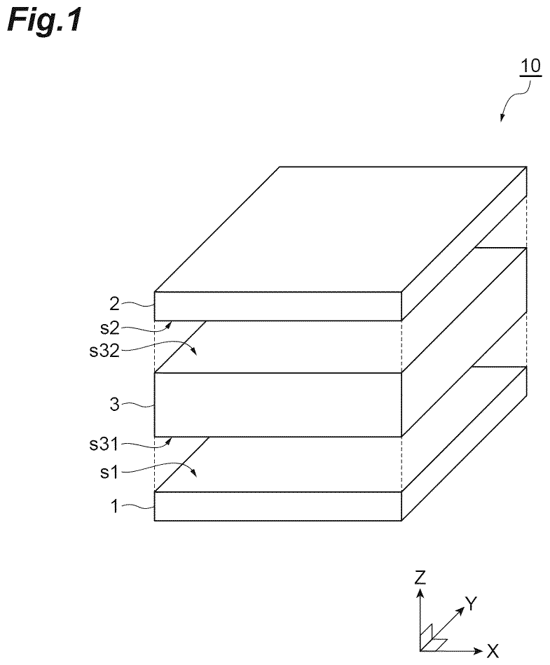

Hereinafter, a preferred embodiment of the present disclosure will be described with reference to the accompanying drawings. In the drawings, an equivalent reference numeral will be given to an equivalent constituent element. The present disclosure is not limited to the following embodiment. X, Y, and Z shown in FIGS. 1 to 3, FIG. 7A, and FIG. 7B represent three coordinate axes orthogonal to each other. A direction of each of the X-axis, the Y-axis, and the Z-axis is common to FIGS. 1 to 3, FIG. 7A, and FIG. 7B.

As shown in FIG. 1, a piezoelectric thin film device 10 according to this embodiment includes a first electrode layer 1 (lower electrode layer), a piezoelectric thin film 3, and a second electrode layer 2 (upper electrode layer). The piezoelectric thin film 3 according to this embodiment contains crystalline aluminum nitride having a wurtzite structure. The piezoelectric thin film 3 has a first main surface s31, and a second main surface s32 located on a rear side of the first main surface s31. “Main surface” is a surface with the largest area among a plurality of surfaces of a polyhedron (for example, the piezoelectric thin film 3 that is a thin rectangular parallelepiped). The first main surface s31 of the piezoelectric thin film 3 is directly stacked on a surface s1 of the first electrode layer 1. A surface s2 of the second electrode layer 2 is directly stacked on the second main surface s32 of the piezoelectric thin film 3. A thickness of the first electrode layer 1 (a width of the first electrode layer 1 in a Z-axis direction) may be approximately or completely uniform. The first main surface s31 of the piezoelectric thin film 3 is a flat plane. The surface s1 of the first electrode layer 1 is also a flat plane. The X-axis and the Y-axis shown in FIG. 1 are parallel to the first main surface s31 of the piezoelectric thin film 3 and the surface s1 of the first electrode layer 1. The Z-axis shown in FIG. 1 is orthogonal to the first main surface s31 of the piezoelectric thin film 3 and the surface s1 of the first electrode layer 1.

A developed interfacial area ratio Sdr of the second main surface s32 of the piezoelectric thin film 3 is from 0.001 to 0.100 (from 0.1% to 10%). The developed interfacial area ratio may be rephrased as a developed surface area ratio. The developed interfacial area ratio Sdr is defined as follows.

A location of any point P contained in any plane XY (that is, a plane XY containing an X-axis and a Y-axis) parallel to the first main surface s31 of the piezoelectric thin film 3 is expressed as (x, y, 0). x is a coordinate of the point P in the X-axis direction, and y is a coordinate of the point P in the Y-axis direction. 0 (zero) is a coordinate of the point P in a Z-axis direction. A location of any point Q contained in the second main surface s32 of the piezoelectric thin film 3 is expressed as (x, y, z). (x, y) of the point Q match (x, y) of the point P. z of the point Q is a coordinate of the point Q in the Z-axis direction. An absolute value of z corresponds to a distance between the point P and the point Q. Since the second main surface s32 of the piezoelectric thin film 3 is a surface extending along the plane XY in a three-dimensional coordinate system composed of the X-axis, the Y-axis, and the Z-axis, when (x, y) of the point Q contained in the second main surface s32 is specified, z of the point Q is determined to one value. Therefore, the second main surface s32 of the piezoelectric thin film 3 is expressed by a function of z=f(x, y). A defined region (plane) within the plane XY parallel to the first main surface s31 of the piezoelectric thin film 3 is expressed as A. An area B of the second main surface s32 in the defined region A (integral region) is expressed by the following Mathematical Formula 1. The area B can be rephrased as an area of a portion, which overlaps the defined region A (integral region) in a direction (Z-axis direction) orthogonal to the first main surface s31, within the second main surface s32. The developed interfacial area ratio Sdr of the second main surface s32 is defined by the following Mathematical Formula 2. The following Mathematical Formula 2 is simplified like the following Mathematical Formula 3. For convenience of notation, an area of the defined region A is also expressed as A in the following Mathematical formulae 2 and 3. The developed interfacial area ratio Sdr of the second main surface s32 of the piezoelectric thin film 3 may be measured by an atomic force microscope (AFM). In a case where the first main surface s31 (the entirety of the first main surface s31) is approximately or completely flat, A in Mathematical Formula 3 may be an area of the first main surface s31 (an area of the entirety of the first main surface s31), and B in Mathematical Formula 3 may be an area of the second main surface s32 (area of the entirety of the second main surface s32).

$$[ Mathematical Formula 1 ]$$

$$B = {\int \int }_{A} \sqrt{1 + {( \frac{\partial f ( x , y )}{\partial x} )}^{2} + {( \frac{\partial f ( x , y )}{\partial y} )}^{2}} dxdy \qquad ( 1 )$$

$$[ Mathematical Formula 2 ]$$

$$Sdr = \frac{1}{A} {\int \int }_{A} \sqrt{1 + {( \frac{\partial f ( x , y )}{\partial x} )}^{2} + {( \frac{\partial f ( x , y )}{\partial y} )}^{2}} - 1 ) dxdy \qquad ( 2 )$$

$$[ Mathematical Formula 3 ]$$

$$Sdr = \frac{B - A}{A} \qquad ( 3 )$$

The developed interfacial area ratio Sdr is one of indexes indicating surface roughness of the second main surface s32 of the piezoelectric thin film 3. The developed interfacial area ratio Sdr of from 0.001 to 0.100 represents that the area of the second main surface s32 of the piezoelectric thin film 3 is larger than an area of a perfect plane. In other words, the developed interfacial area ratio Sdr of from 0.001 to 0.100 represents that an area (adhering area) of an interface between the second main surface s32 and the surface s2 of the second electrode layer 2 is larger than an area of an interface between a perfectly flat plane and the surface s2 of the second electrode layer 2. When the developed interfacial area ratio Sdr is from 0.001 to 0.100, adhesiveness of the second electrode layer 2 to the second main surface s32 of the piezoelectric thin film 3 is improved, and peeling-off of the second electrode layer 2 from the second main surface s32 of the piezoelectric thin film 3 is suppressed. In a case where the developed interfacial area ratio Sdr is less than 0.001, the second electrode layer 2 is likely to be peeled off from the second main surface s32 of the piezoelectric thin film 3. In a case where the developed interfacial area ratio Sdr is more than 0.100, the second electrode layer 2 is likely to be peeled off from the second main surface s32 of the piezoelectric thin film 3, and piezoelectric properties (for example, d₃₃) of the piezoelectric thin film 3 are likely to deteriorate.

For the reason that the peeling-off of the second electrode layer 2 from the second main surface s32 of the piezoelectric thin film 3 is likely to be suppressed, and that the piezoelectric properties of the piezoelectric thin film 3 are likely to be improved, the developed interfacial area ratio Sdr of the second main surface s32 of the piezoelectric thin film 3 may be from 0.002 to 0.055 (from 0.2% to 5.5%), or from 0.004 to 0.043 (from 0.4% to 4.3%). From the same reason, the developed interfacial area ratio Sdr of the second main surface s32 of the piezoelectric thin film 3 may be more than 0.015 and equal to or less than 0.100 (more than 1.5% and equal to or less than 10%), more than 0.015 and equal to or less than 0.055 (more than 1.5% and equal to or less than 5.5%), more than 0.015 and equal to or less than 0.043 (more than 1.5% and equal to or less than 4.3%), from 0.020 to 0.100 (from 2.0% to 10%), from 0.020 to 0.055 (from 2.0% to 5.5%), or from 0.020 to 0.043 (from 2.0% to 4.3%).

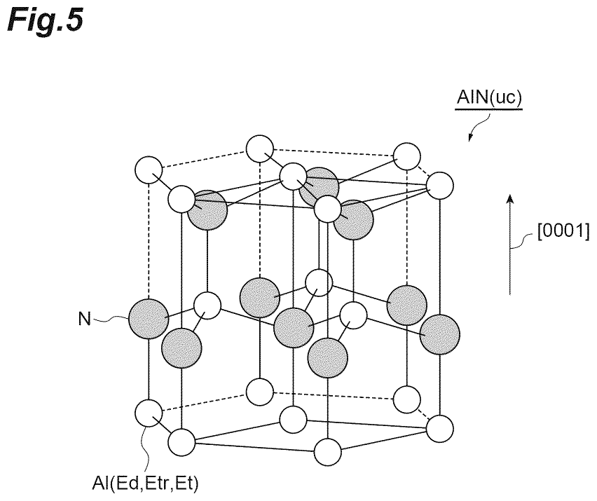

The crystalline aluminum nitride contained in the piezoelectric thin film 3 has a hexagonal wurtzite structure. That is, as shown in FIG. 5, a unit cell uc of the aluminum nitride (wurtzite structure) is a hexagonal column. For example, in a case where the unit cell uc consists only of Al and N, the unit cell uc may be a regular hexagonal column.

The aluminum nitride may contain a divalent element Ed and a tetravalent element Et. A part of Al in the unit cell uc of the wurtzite structure may be substituted with the divalent element Ed or the tetravalent element Et. The piezoelectric thin film 3 may consist only of AlN containing the divalent element Ed and the tetravalent element Et. That is, the piezoelectric thin film 3 may consist only of Al, N, the divalent element Ed, and the tetravalent element Et.

The aluminum nitride may contain a trivalent element Etr. A part of Al in the unit cell uc of the wurtzite structure may be substituted with the trivalent element Etr. The piezoelectric thin film 3 may consist only of AlN containing the trivalent element Etr. That is, the piezoelectric thin film 3 may consist only of Al, N, and the trivalent element Etr.

The aluminum nitride may contain all of the divalent element Ed, the trivalent element Etr, and the tetravalent element Et. The piezoelectric thin film 3 may consist only of AlN containing the divalent element Ed, the trivalent element Etr, and the tetravalent element Et. That is, the piezoelectric thin film 3 may consist only of Al, N, the divalent element Ed, the trivalent element Etr, and the tetravalent element Et.

The piezoelectric thin film 3 may consist only of pure AlN. That is, the piezoelectric thin film 3 may consist only of Al and N. As to be described later, the piezoelectric thin film 3 may further contain other elements in addition to Al, N, the divalent element Ed, the trivalent element Etr, and the tetravalent element Et.

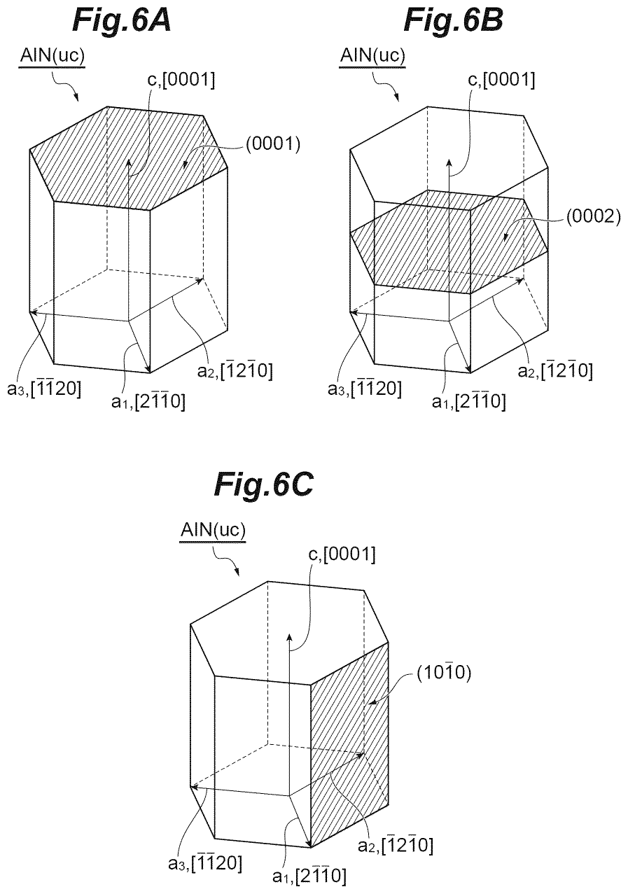

The unit cell uc shown in FIG. 6A, FIG. 6B, and FIG. 6C are identical to the unit cell uc shown in FIG. 5. One element among aluminum, the divalent element Ed, the trivalent element Etr, and the tetravalent element Et may be disposed at each of twelve vertexes of the unit cell uc (hexagonal column) shown in each of FIG. 6A, FIG. 6B, and FIG. 6C. However, Al, N, the divalent element Ed, the trivalent element Etr, and the tetravalent element Et are omitted in FIG. 6A, FIG. 6B, and FIG. 6C to illustrate each fundamental vector and each lattice plane of the unit cell uc. a₁, a₂, a₃, and c in the unit cell uc are fundamental vectors (crystal axes) constituting the unit cell uc. A direction of a₁ is [2−1−10]. A direction of a₂ is [−12−10]. A direction of a₃ is [−1−120]. A direction of c is [0001]. Lengths of a₁, a₂, and a₃ may be approximately equal to each other. The lengths of a₁, a₂, and a₃ may be completely the same each other. Any of a₁, a₂, and a₃ may be approximately orthogonal to c. Any of a₁, a₂, and a₃ may be completely orthogonal to c. An angle between a₁, a₂, and a₃ may be approximately 120°. The angle between a₁, a₂, and a₃ may be completely 120°. FIG. 6A shows a (0001) plane of the aluminum nitride. FIG. 6B shows a (0002) plane of the aluminum nitride. FIG. 6C shows a (10−10) plane of the aluminum nitride. The (0001) plane is approximately or completely parallel to the (0002) plane. The (10−10) plane is approximately or completely orthogonal to the (0002) plane.

For example, the crystal structure of the aluminum nitride may be specified by an X-ray diffraction method and an electron diffraction method. For example, a diffracted X-ray of a lattice plane (for example, the (0002) plane) that is approximately or completely parallel to the first main surface s31 of the piezoelectric thin film 3 among a plurality of lattice planes of the aluminum nitride may be detected by an out-of-plane diffraction method in the second main surface s32 of the piezoelectric thin film 3. For example, a diffracted X-ray of a lattice plane (for example, the (10−10) plane) that is approximately or completely orthogonal to the first main surface s31 of the piezoelectric thin film 3 among the plurality of lattice planes of the aluminum nitride may be detected by an in-plane diffraction method in the second main surface s32 of the piezoelectric thin film 3.

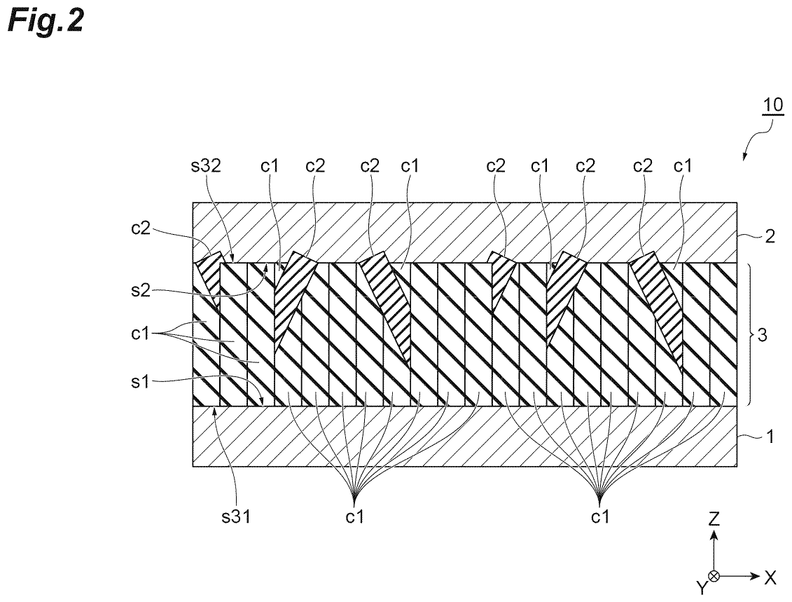

FIG. 2 shows a schematic cross-section of the piezoelectric thin film device 10 shown in FIG. 1. The cross-section shown in FIG. 2 is orthogonal to the first main surface s31 of the piezoelectric thin film 3. As shown in FIG. 2, the piezoelectric thin film 3 may contain a plurality of first crystal grains c1 and a plurality of second crystal grains c2. The piezoelectric thin film 3 may consist only of the plurality of first crystal grains c1 and the plurality of second crystal grains c2. Both the first crystal grains c1 and the second crystal grains c2 contain crystalline aluminum nitride having the wurtzite structure. Each of the plurality of first crystal grains c1 may be columnar crystal. Each of the plurality of second crystal grains c2 may also be a columnar crystal. Each of the plurality of first crystal grains c1 may be a single crystal or a polycrystal. Each of the plurality of second crystal grains c2 may also be a single crystal or a polycrystal.

The plurality of first crystal grains c1 are exposed on the second main surface s32 of the piezoelectric thin film 3. Some first crystal grains c1 among all of the first crystal grains c1 contained in the piezoelectric thin film 3 are likely to be exposed on the second main surface s32 of the piezoelectric thin film 3. All of the first crystal grains c1 contained in the piezoelectric thin film 3 may be exposed on the second main surface s32 of the piezoelectric thin film 3. Instead of the entirety of each of the first crystal grains c1, an end of each of the first crystal grains c1 is likely to be exposed on the second main surface s32 of the piezoelectric thin film 3.

The plurality of second crystal grains c2 are exposed on the second main surface s32 of the piezoelectric thin film 3. Some second crystal grains c2 among all of the second crystal grains c2 contained in the piezoelectric thin film 3 are likely to be exposed on the second main surface s32 of the piezoelectric thin film 3. All of the second crystal grains c2 contained in the piezoelectric thin film 3 may be exposed on the second main surface s32 of the piezoelectric thin film 3. Instead of the entirety of each of the second crystal grains c2, an end of each of the second crystal grains c2 is likely to be exposed on the second main surface s32 of the piezoelectric thin film 3.

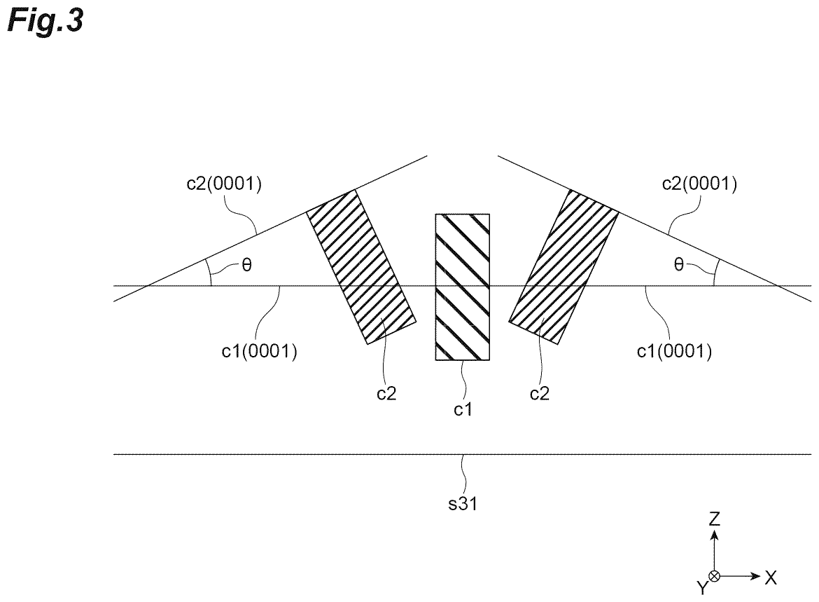

FIG. 3 shows a direction of the (0001) plane of the aluminum nitride in the first crystal grains c1 contained in the cross-section shown in FIG. 2, a direction of the (0001) plane of the aluminum nitride in the second crystal grains c2 contained in the cross-section shown in FIG. 2, and a direction of the first main surface s31 of the piezoelectric thin film 3 shown in FIG. 2. A first reference plane c1 (0001) shown in FIG. 3 is a plane containing the (0001) plane of the aluminum nitride in the first crystal grains c1. A second reference plane c2 (0001) shown in FIG. 3 is a plane containing the (0001) plane of the aluminum nitride in the second crystal grains c2. In the cross-section shown in FIG. 3, any of the first reference plane c1 (0001), the second reference plane c2 (0001), and the first main surface s31 of the piezoelectric thin film 3 is represented by a straight line.

As shown in FIG. 3, the (0001) plane (that is, the first reference plane c1 (0001)) of the aluminum nitride in each of the first crystal grains c1 is approximately or completely parallel to the first main surface s31 of the piezoelectric thin film 3. In other words, the (0001) plane of the aluminum nitride in each of the first crystal grains c1 is approximately or completely parallel to the surface s1 of the first electrode layer 1. The above-described defined region A (integral region) may be a plane parallel to the (0001) plane of each of the first crystal grains c1.

On the other hand, the (0001) plane (that is, the second reference plane c2 (0001)) of the aluminum nitride in each of the second crystal grains c2 is inclined to the (0001) plane (that is, the first reference plane c1 (0001)) of the aluminum nitride in each of the first crystal grains c1. In other words, the (0001) plane of the aluminum nitride in each of the second crystal grains c2 is inclined to the first main surface s31 of the piezoelectric thin film 3 and the surface s1 of the first electrode layer 1.

Since the (0001) plane of the aluminum nitride in each of the first crystal grains c1 is approximately or completely parallel to the first main surface s31 (flat plane) of the piezoelectric thin film 3, only at least one lattice plane among the (0001) plane and the (0002) plane of the aluminum nitride in each of the first crystal grains c1 is likely to be exposed on the rear surface of the first main surface s31. In other words, only at least one lattice plane among the (0001) plane and the (0002) plane of the aluminum nitride in each of the first crystal grains c1 is likely to be exposed on the second main surface s32. Accordingly, in the second main surface s32 of the piezoelectric thin film 3, a portion where only one or more first crystal grains c1 is exposed is approximately or completely parallel to the first main surface s31 of the piezoelectric thin film 3. In other words, a portion consisting only of one or more first crystal grains c1 in the second main surface s32 of the piezoelectric thin film 3 is less likely to include surface defects such as kinks and steps, and is likely to be flat.

On the other hand, the (0001) plane of the aluminum nitride in each of the second crystal grains c2 is inclined to the (0001) plane of the aluminum nitride in the first crystal grains c1. Accordingly, not only the (0001) plane and the (0002) plane of the aluminum nitride in the second crystal grains c2, but also another lattice plane (for example, a (10−10) plane) in each of the second crystal grains c2 is also likely to be exposed on the second main surface s32. Accordingly, a portion where one or more second crystal grains c2 are exposed in the second main surface s32 of the piezoelectric thin film 3 is likely to include surface defects such as kinks and steps. In other words, a portion where one or more second crystal grains c2 are exposed in the second main surface s32 of the piezoelectric thin film 3 is likely to be an inclined convex portion, and a portion where one or more first crystal grains c1 are exposed in the second main surface s32 of the piezoelectric thin film 3 is likely to be a flat plane or a concave portion.

From the above reason, when the piezoelectric thin film 3 contains the plurality of second crystal grains c2 in addition to the plurality of first crystal grains c1, a plurality of the convex portions and a plurality of the concave portions are likely to be formed on the second main surface s32 of the piezoelectric thin film 3. As a result, the second main surface s32 is likely to be rough, and the developed interfacial area ratio Sdr of the second main surface s32 is likely to be a value of from 0.001 to 0.100. Since the convex portions and the concave portions formed on the second main surface s32 of the piezoelectric thin film 3 and the surface s2 of the second electrode layer 2 engage each other, adhesiveness of the second electrode layer 2 to the second main surface s32 of the piezoelectric thin film 3 is likely to be improved. That is, due to an anchor effect derived from the convex portions and the concave portions formed on the second main surface s32 of the piezoelectric thin film 3, peeling-off of the second electrode layer 2 from the second main surface s32 of the piezoelectric thin film 3 is likely to be suppressed.

The aluminum nitride is polarized in a crystal orientation (that is, [0001]) orthogonal to the (0001) plane. Accordingly, the (0001) plane of the aluminum nitride in the plurality of first crystal grains c1 is oriented to be approximately or completely parallel to the first main surface s31 of the piezoelectric thin film 3 (the surface s1 of the first electrode layer 1), and thus piezoelectric properties of the piezoelectric thin film 3 are likely to be improved. In addition, since the second crystal grains c2 inclined to the first crystal grains c1 grow in a process of forming the piezoelectric thin film 3, a stress causing the first crystal grains c1 to extend in the c-axis direction is likely to act on the first crystal grains c1 in growth from the second crystal grains c2. As a result, crystallinity of the first crystal grains c1 is likely to be improved, orientation of the (0001) plane of the aluminum nitride in the first crystal grains c1 is likely to be improved, and the piezoelectric properties of the piezoelectric thin film 3 are likely to be improved.

A diffracted X-ray derived from the (0002) plane of the aluminum nitride in the plurality of first crystal grains c1 is detected by the out-of-plane diffraction method in the second main surface s32 of the piezoelectric thin film 3. The (0001) plane is approximately or completely parallel to the (0002) plane. Accordingly, it is possible to confirm that the (0001) plane of the aluminum nitride in the plurality of first crystal grains c1 is approximately or completely parallel to the first main surface s31 of the piezoelectric thin film 3 by detecting the diffracted X-ray derived from the (0002) plane of the aluminum nitride in the plurality of first crystal grains c1 by the out-of-plane diffraction method. A diffracted X-ray derived from the (10−10) plane of the aluminum nitride in the plurality of first crystal grains c1 is detected by the in-plane diffraction method in the second main surface s32 of the piezoelectric thin film 3.

As to be described later, an inclination of the (0001) plane of the aluminum nitride in the second crystal grains c2 can be confirmed by an electron diffraction method.

As illustrated in FIG. 3, an angle θ between the first reference plane c1 (0001) and the second reference plane c2 (0001) can be rephrased as an angle θ between the (0001) plane of the aluminum nitride in the first crystal grains c1 and the (0001) plane of the aluminum nitride in the second crystal grains c2. For example, the angle θ between the (0001) plane of the aluminum nitride in the first crystal grains c1 and the (0001) plane of the aluminum nitride in the second crystal grains may be from 0.1° to 30°. As the angle θ increases, the convex portions and the concave portions are likely to be formed on the second main surface s32 of the piezoelectric thin film 3. That is, as the angle θ increases, the developed interfacial area ratio Sdr is likely to increase. In a case where the angle θ is from 0.1° to 30°, peeling-off of the second electrode layer 2 from the second main surface s32 of the piezoelectric thin film 3 is likely to be suppressed, and the piezoelectric properties of the piezoelectric thin film 3 are likely to be improved. From the same reason, the angle θ may be from 0.4° to 17°.

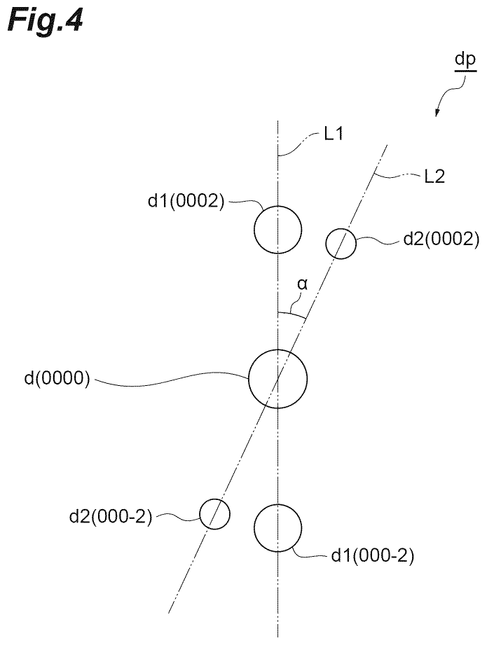

An electron diffraction pattern dp shown in FIG. 4 is measured by causing an electron beam to be incident to any one of second crystal grains 2 exposed on the cross-section of the piezoelectric thin film 3 (cross-section orthogonal to the first main surface s31 of the piezoelectric thin film 3). A central spot d (0000) in the electron diffraction pattern dp is a spot of an electron beam that is not diffracted in the piezoelectric thin film 3. A diffraction spot d1 (0002) in the electron diffraction pattern dp is a spot of an electron beam diffracted on the (0002) plane of the aluminum nitride in the first crystal grains c1. A diffraction spot d1 (000−2) in the electron diffraction pattern dp is a spot of an electron beam diffracted on a (000−2) plane of the aluminum nitride in the first crystal grains c1. A diffraction spot d2 (0002) in the electron diffraction pattern dp is a spot of an electron beam diffracted on the (0002) plane of the aluminum nitride in the second crystal grains c2. A diffraction spot d2 (000−2) in the electron diffraction pattern dp is a spot of an electron beam diffracted on a (000−2) plane of the aluminum nitride in the second crystal grains c2. Spots of electron beams diffracted on lattice planes other than the (0002) plane and the (000−2) plane are omitted in FIG. 4 for convenience of explanation.

A ratio of a total volume of the plurality of second crystal grains c2 in the piezoelectric thin film 3 is smaller than a ratio of a total volume of the plurality of first crystal grains c1 in the piezoelectric thin film 3. For example, the ratio of the total volume of the plurality of second crystal grains c2 in the piezoelectric thin film 3 may be from 0.005% by volume to 25.0% by volume, and the ratio of the total volume of the plurality of first crystal grains c1 in the piezoelectric thin film 3 may be from 75.0% by volume to 99.995% by volume. Due to the magnitude correlation of the volume ratio, the electron diffraction pattern dp measured by causing an electron beam to be incident to one of the second crystal grains c2 contains not only a diffraction spot derived from the second crystal grains c2 but also a diffraction spot derived from the first crystal grains c1 existing near the second crystal grains c2. In addition, due to the magnitude correlation of the volume ratio, the intensity (luminosity) of each diffraction spot derived from the second crystal grains c2 is lower than the intensity of each diffraction spot derived from the first crystal grains c1, and a diameter of the diffraction spot derived from the second crystal grains c2 is smaller than a diameter of the diffraction spot derived from the first crystal grains c1.

On the other hand, in a case where the electron diffraction pattern is measured by causing an electron beam to be incident to any one of first crystal grains c1 exposed on the cross-section of the piezoelectric thin film 3 (cross-section orthogonal to the first main surface s31 of the piezoelectric thin film 3), the electron diffraction pattern is likely to contain only a diffraction spot derived from the first crystal grains c1, and is less likely to contain a diffraction spot derived from the second crystal grains c2. Accordingly, it is possible to identify the diffraction spot derived from the first crystal grains c1 and the diffraction spot derived from the second crystal grains c2 by comparing the electron diffraction pattern measured by incidence of the electron beam to the first crystal grains c1 with the electron diffraction pattern dp measured by incidence of the electron beam to the second crystal grains c2.

A reference line L1 in the electron diffraction pattern dp is a straight line passing through the center of the central spot d (0000) and the center of the diffraction spot d1 (0002) derived from the (0002) plane of the aluminum nitride in the first crystal grains c1. A reference line L2 in the electron diffraction pattern dp is a straight line passing through the center of the central spot d (0000) and the center of the diffraction spot d2 (0002) derived from the (0002) plane of the aluminum nitride in the second crystal grains c2. Since the (0002) plane is parallel to the (0001) plane, the angle θ between the (0001) plane of the aluminum nitride in the first crystal grains c1 and the (0001) plane of the aluminum nitride in the second crystal grains c2 can be specified from an angle α between the reference line L1 and the reference line L2. That is, the angle α between the reference line L1 and the reference line L2 is equal to the angle θ between the (0001) plane of the aluminum nitride in the first crystal grains c1 and the (0001) plane of the aluminum nitride in the second crystal grains.

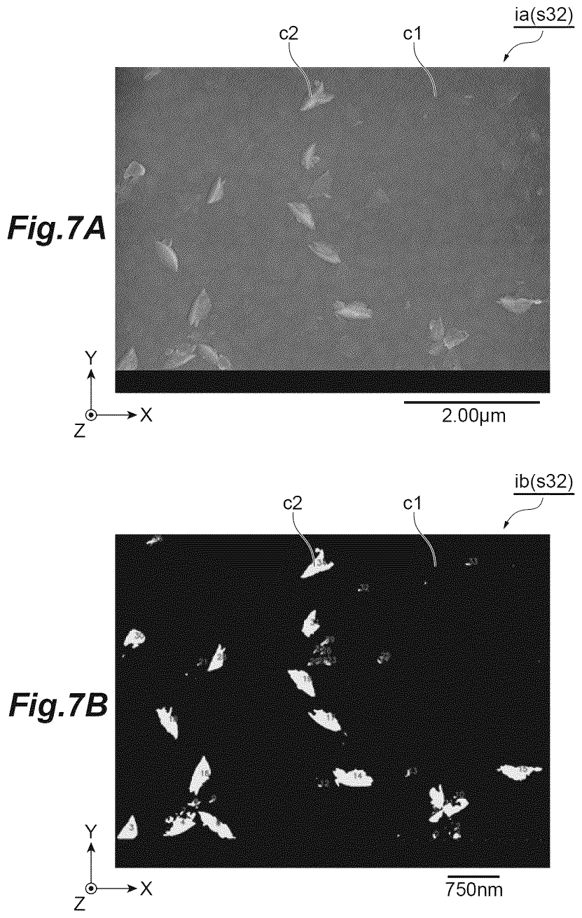

FIG. 7A is a secondary electron image ia of a part of the second main surface s32 of the piezoelectric thin film 3. The secondary electron image ia of the second main surface s32 is taken by a scanning electron microscope (SEM). The secondary electron image ia of the second main surface s32 is approximately or completely parallel to the first main surface s31 of the piezoelectric thin film 3. In other words, the secondary electron image ia of the second main surface s32 may be approximately or completely parallel to the (0001) plane of the aluminum nitride in the plurality of the first crystal grains c1.

As described above, in a case where the plurality of second crystal grains c2 are exposed on the second main surface s32 of the piezoelectric thin film 3, the secondary electron image ia contains the plurality of first crystal grains c1 exposed on the second main surface s32 and the plurality of second crystal grains c2 exposed on the second main surface s32. As described above, since ends of the plurality of second crystal grains c2 exposed on the second main surface s32 are inclined in the second main surface s32, luminance of each of the second crystal grains c2 in the secondary electron image ia is different from luminance of each of the first crystal grains c1 in the secondary electron image ia. That is, the first crystal grains c1 and the second crystal grains c2 in the secondary electron image ia are identified by a difference in contrast (a difference in luminance). A bright portion in the secondary electron image ia is the second crystal grains c2 and a dark portion in the secondary electron image ia is the first crystal grains c1. The secondary electron image ia shown in FIG. 7A shows that the plurality of second crystal grains c2 (plurality of convex portions) are dispersed in a flat plane consisting of the plurality of first crystal grains c1.

A monochrome image ib shown in FIG. 7B is a second electron image ia binarized on the basis of a difference in luminance between each of the first crystal grains c1 and each of the second crystal grains c2 in the secondary electron image ia. When using the monochrome image ib, a contour, dimensions, and an area of each of the plurality of second crystal grains c2 exposed on the second main surface s32 can be more accurately measured.

A ratio (area fraction RA) of a total area of the plurality of second crystal grains c2 in the secondary electron image ia (monochrome image ib) may be from 0.01% to 20%. The total area of all of the second crystal grains c2 exposed within the secondary electron image ia may be expressed as A_{TOTAL}, a total area of the secondary electron image ia may be expressed as Ai, and the area fraction RA may be defined as (A_{TOTAL}/Ai)×100. That is, A_{TOTAL}/Ai may be from 0.01% to 20% (from 0.0001 to 0.2). A secondary electron image ia of each of ten different portions contained in the second main surface s32 of the piezoelectric thin film 3 may be taken, and an average value of the ratio (area fraction RA) of the total area of the plurality of second crystal grains c2 in secondary electron images ia (monochrome images ib) of the ten different portions may be from 0.01% to 20%. In a case where the area fraction RA is from 0.01% to 20%, peeling-off of the second electrode layer 2 from the second main surface s32 of the piezoelectric thin film 3 is likely to be suppressed. In addition, in a case where the area fraction RA is from 0.01% to 20%, the crystallinity of the first crystal grains c1 is likely to be improved, the orientation of the (0001) plane of the aluminum nitride in the first crystal grains c1 is likely to be improved, and the piezoelectric properties of the piezoelectric thin film 3 are likely to be improved.

A Heywood diameter d of each of the second crystal grains c2 which is measured in the secondary electron image ia (monochrome image ib) may be from 5 nm to 2000 nm. An area of any one of second crystal grains c2 measured in the secondary electron image ia (monochrome image ib) may be expressed as A_{C2}. A Heywood diameter d of the any one of the second crystal grains c2 may be defined as (4A_{C2}/π)^{1/2}. (4A_{C2}/π)^{1/2} corresponds to a diameter of a circle whose area is A_{C2}. That is, the Heywood diameter d can be rephrased as an equivalent circle diameter. In a case where the Heywood diameter d is from 5 nm to 2000 nm, the developed interfacial area ratio Sdr of the second main surface s32 is likely to be a value of from 0.001 to 0.100, and peeling-off of the second electrode layer 2 from the second main surface s32 of the piezoelectric thin film 3 is likely to be suppressed.

Any image analysis software may be used in binarization of the secondary electron image ia, and measurement of the area fraction RA and the Heywood diameter of the second crystal grains. The image analysis software may be a commercially available article or an article not for sale. For example, as the image analysis software, Mac-View manufactured by Mountech Co., Ltd. may be used.

As described above, the aluminum nitride contained in the piezoelectric thin film 3 may contain the divalent element Ed and the tetravalent element Et. Alternately, the aluminum nitride contained in the piezoelectric thin film 3 may contain the trivalent element Etr. The aluminum nitride contained in the piezoelectric thin film 3 may contain all of the divalent element Ed, the trivalent element Etr, and the tetravalent element Et. Due to doping of the aluminum nitride with the divalent element Ed and the tetravalent element Et, or doping of the aluminum nitride with the trivalent element Etr, the wurtzite structure of the aluminum nitride is distorted, or the intensity of chemical bonding between atoms in the wurtzite structure varies. As a result, the piezoelectric thin film 3 is likely to contain both the first crystal grains c1 and the second crystal grains c2, the developed interfacial area ratio Sdr is likely to be controlled to from 0.001 to 0.100, and the piezoelectric properties of the piezoelectric thin film 3 are likely to be improved. The divalent element Ed may be at least one kind of element selected from the group consisting of magnesium (Mg), calcium (Ca), strontium (Sr), and barium (Br). The trivalent element Etr may be at least one kind of element selected from the group consisting of scandium (Sc), yttrium (Y), lanthanoid, and indium (In). The tetravalent element Et may be at least one kind of element selected from the group consisting of zirconium (Zr), germanium (Ge), titanium (Ti), and hafnium (Hf).

A content of aluminum in the aluminum nitride may be expressed as [Al] atomic % ([Al] mol %). The sum of a content of the divalent element Ed in the aluminum nitride may be expressed as [Ed] atomic % ([Ed] mol %). For example, a content of magnesium in the aluminum nitride may be expressed as [Mg] atomic % (Mg mol %). The sum of a content of the trivalent element Etr in the aluminum nitride may be expressed as [Etr] atomic % ([Etr] mol %). For example, a content of scandium in the aluminum nitride may be expressed as [Sc] atomic % ([Sc] mol %). The sum of a content of the tetravalent element Et in the aluminum nitride may be expressed as [Et] atomic % ([Et] mol %). For example, a content of zirconium in the aluminum nitride may be expressed as [Zr] atomic % ([Zr] mol %). For example, a content of hafnium in the aluminum nitride may be expressed as [Hf] atomic % ([Hf] mol %).

([Ed]+[Et])/([Al]+[Ed]+[Et]) may be from 0.03 to 0.60 (from 3% to 60%) or from 0.40 to 0.44 (from 40% to 44%). For example, ([Mg]+[Zr])/([Al]+[Mg]+[Zr]) may be from 0.03 to 0.60 (from 3% to 60%) or from 0.40 to 0.44 (from 40% to 44%). For example, ([Mg]+[Hf])/([Al]+[Mg]+[Hf]) may be from 0.03 to 0.60 (from 3% to 60%) or from 0.03 to 0.59 (from 3% to 59%). In a case where ([Ed]+[Et])/([Al]+[Ed]+[Et]) is from 0.03 to 0.60, from 0.03 to 0.59, or from 0.40 to 0.44, the developed interfacial area ratio Sdr is likely to be controlled to from 0.001 to 0.100. In addition, in a case where ([Ed]+[Et])/([Al]+[Ed]+[Et]) is from 0.03 to 0.60, from 0.03 to 0.59, or from 0.40 to 0.44, the piezoelectric properties of the piezoelectric thin film 3 are likely to be improved.

[Ed]/([Ed]+[Et]) may be from 0.25 to 0.60, or from 0.40 to 0.56. For example, [Mg]/([Mg]+[Zr]) may be from 0.25 to 0.60, or from 0.40 to 0.56. For example, [Hf]/([Mg]+[Hf]) may be from 0.25 to 0.60, or from 0.26 to 0.58. In a case where [Ed]/([Ed]+[Et]) is from 0.25 to 0.60, from 0.26 to 0.58, or from 0.40 to 0.56, the developed interfacial area ratio Sdr is likely to be controlled to from 0.001 to 0.100. In addition, in a case where [Ed]/([Ed]+[Et]) is from 0.40 to 0.56, the piezoelectric properties of the piezoelectric thin film 3 are likely to be improved.

[Etr]/([Al]+[Etr]) may be from 0.10 to 0.40 (from 10% to 40%). For example, [Sc]/([Al]+[Sc]) may be from 0.10 to 0.40 (from 10% to 40%). In a case where [Etr]/([Al]+[Etr]) is from 0.10 to 0.40, the developed interfacial area ratio Sdr is likely to be controlled to from 0.001 to 0.100. In addition, in a case where [Etr]/([Al]+[Etr]) is from 0.10 to 0.40, the piezoelectric properties of the piezoelectric thin film 3 are likely to be improved.

The aluminum nitride contained in the piezoelectric thin film 3 may further contain at least one kind of additive element selected from the group consisting of a monovalent element and a pentavalent element. The monovalent element may be at least one kind of element selected from the group consisting of lithium (Li), sodium (Na), potassium (K), rubidium (Rb), and cesium (Cs). The pentavalent element may be at least one kind of element selected from the group consisting of chromium (Cr), vanadium (V), niobium (Nb), and tantalum (Ta). The aluminum nitride contained in the piezoelectric thin film 3 may further contain other elements such as oxygen (O) and argon (Ar).

The first electrode layer 1 may contain at least one kind of element selected from the group consisting of platinum (Pt), iridium (Ir), gold (Au), rhodium (Rh), palladium (Pd), silver (Ag), nickel (Ni), copper (Cu), aluminum (Al), molybdenum (Mo), Tungsten (W), vanadium (V), chromium (Cr), niobium (Nb), tantalum (Ta), ruthenium (Ru), zirconium (Zr), hafnium (Hf), titanium (Ti), yttrium (Y), scandium (Sc), and magnesium (Mg). The first electrode layer 1 may be a metal elementary substance or an alloy.

The second electrode layer 2 may contain at least one kind of element selected from the group consisting of Pt, Ir, Au, Rh, Pd, Ag, Ni, Cu, Al, Mo, W, V, Cr, Nb, Ta, Ru, Zr, Hf, Ti, Y, Sc, and Mg. The second electrode layer 2 may be a metal elementary substance or an alloy.

The piezoelectric thin film device 10 may further include a substrate. The first electrode layer 1 may be directly or indirectly stacked on the substrate. The piezoelectric thin film device 10 may further include an adhesive layer. The adhesive layer may be interposed between the substrate and the first electrode layer 1. That is, the first electrode layer 1 may be indirectly stacked on the substrate through the adhesive layer.

For example, the substrate may be a semiconductor substrate (a silicon substrate, a gallium arsenide substrate, or the like), an optical crystal substrate (sapphire substrate or the like), an insulator substrate (a glass substrate, a ceramic substrate, or the like), a metal substrate (a stainless steel plate or the like), or a silicon-on-insulator (SOI) substrate. The substrate may be crystalline. For example, the substrate may be a single crystal or a polycrystal.

For example, the adhesive layer may contain at least one kind of element selected from the group consisting of aluminum (Al), silicon (Si), titanium (Ti), zinc (Zn), yttrium (Y), zirconium (Zr), chromium (Cr), molybdenum (Mo), hafnium (Hf), tantalum (Ta), tungsten (W), platinum (Pt), and ruthenium (Ru). The adhesive layer may be a metal elementary substance, an alloy, or a compound (an oxide or the like). The adhesive layer may be another piezoelectric thin film (for example, aluminum nitride), a polymer, or ceramics. The adhesive layer has a function of suppressing peeling-off of the first electrode layer due to mechanical impact or the like. The adhesive layer may be rephrased as an interfacial layer, a support layer, a buffer layer, or an intermediate layer.

For example, a thickness of the substrate may be from 50 μm to 10000 μm. For example, a thickness of the adhesive layer may be from 0.003 μm to 2 μm. For example, a thickness of the first electrode layer 1 may be from 0.01 μm to 1 μm. For example, a thickness of the piezoelectric thin film 3 may be from 100 nm to 30000 nm. For example, a thickness of the second electrode layer 2 may be from 0.01 μm to 1 μm. The thickness of each of the substrate, the adhesive layer, the first electrode layer 1, the piezoelectric thin film 3, and the second electrode layer 2 may be approximately or completely uniform.

A crystal structure of each of the substrate, the adhesive layer, the first electrode layer, the piezoelectric thin film, and the second electrode layer may be specified by an X-ray diffraction method and an electron diffraction method. The composition of each of the substrate, the adhesive layer, the first electrode layer, the piezoelectric thin film, and the second electrode layer may be specified by at least any one analysis method among an X-ray fluorescence analysis (XRF), an X-ray photoelectron spectroscopy (XPS), an energy dispersive X-ray analysis (EDX), inductively coupled plasma mass spectrometry (ICP-MS), laser ablation inductively coupled plasma mass spectrometry (LA-ICP-MS), and electron beam microanalyzer (EPMA). The thickness of each of the substrate, the adhesive layer, the first electrode layer, the piezoelectric thin film, and the second electrode layer may be measured by a scanning electron microscope on a cross-section of the piezoelectric thin film device which cross-section is parallel to a stacking direction.

Each of the adhesive layer, the first electrode layer, the piezoelectric thin film, and the second electrode layer may be sequentially stacked on a surface of the substrate by a vapor deposition method such as sputtering. Particularly, the piezoelectric thin film is formed by radio frequency (RF) magnetron sputtering. Each of the adhesive layer, the first electrode layer, the piezoelectric thin film, and the second electrode layer may be formed by sputtering using at least one target. Each of the adhesive layer, the first electrode layer, the piezoelectric thin film, and the second electrode layer may be formed by sputtering using a plurality of targets. Each of the targets may contain at least one kind of element among elements constituting each layer or the piezoelectric thin film. The composition of each of the adhesive layer, the first electrode layer, the piezoelectric thin film, and the second electrode layer can be controlled to a desired composition by selection of targets having a predetermined composition, and a combination thereof. For example, the target may be a metal elementary substance, an alloy, or an oxide. For example, in a case where the piezoelectric thin film is aluminum nitride containing a divalent element and a tetravalent element, a target consisting of aluminum, a target consisting of the divalent element, and a target consisting of the tetravalent element may be used. One or more alloys consisting of two or more kinds of elements selected from the group consisting of aluminum, divalent elements, and tetravalent elements may be used as the target. For example, in a case where the piezoelectric thin film is aluminum nitride containing a trivalent element, a target consisting of aluminum, and a target consisting of the trivalent element may be used. For example, in a case where the piezoelectric thin film is aluminum nitride containing the divalent element, the trivalent element, and the tetravalent element, a target consisting of aluminum, a target consisting of the divalent element, a target consisting of the trivalent element, and a target consisting of the tetravalent element may be used. One or more alloys consisting of two or more kinds of elements selected from the group consisting of aluminum, the divalent element, the trivalent element, and the tetravalent element may be used as the target. A composition of an atmosphere of the sputtering may be a control factor of the composition of each of the adhesive layer, the first electrode layer, the piezoelectric thin film, and the second electrode layer. For example, a nitrogen gas is a raw material of the piezoelectric thin film (aluminum nitride). Input power (power density) applied to a cathode in which each target is installed may be a control factor of the composition and the thickness of each of the adhesive layer, the first electrode layer, the piezoelectric thin film, and the second electrode layer. A total pressure of the atmosphere of the sputtering, a partial pressure or a concentration of a source gas in the atmosphere, a duration time of the sputtering for each target, a temperature of a surface of the substrate, a substrate bias, and the like also may be control factors of the composition and the thickness of each of the adhesive layer, the first electrode layer, the piezoelectric thin film, and the second electrode layer. A piezoelectric thin film having a desired shape or pattern may be formed by etching (for example, plasma etching).

In RF magnetron sputtering in the related art, after supply of cathode power (power) to a cathode in which a target is installed and supply of substrate bias (power) to a substrate electrode (substrate including a first electrode layer) are performed in parallel, the supply of the cathode power and the supply of the substrate bias are stopped simultaneously. On the other hand, in a step of forming the piezoelectric thin film according to this embodiment, after supply of the cathode power and supply of the substrate bias are performed in parallel, the supply of the cathode power is stopped first, and the supply of the substrate bias is further continued for a predetermined time. In addition, in the process of forming the piezoelectric thin film according to this embodiment, the substrate bias is 20 W. In the process in which the supply of the cathode power and the supply of the substrate bias are performed in parallel, partial epitaxial growth of a plurality of first crystal grains consisting of aluminum nitride in which the (0001) plane is oriented is likely to progress on a surface of the first electrode layer. However, since the supply of the substrate bias of 20 W is continued even after the supply of the cathode power is stopped, atoms (Al, a divalent element Ed, a trivalent element Etr, a tetravalent element Et, and the like) reaching the surface of the growing aluminum nitride from the target are likely to move in the vicinity of the surface of the aluminum nitride. As a result, a plurality of lattice defects are likely to be formed on the surface of the aluminum nitride. A plurality of abnormal grains (second crystal grains) grow from the lattice defects, and thus a second main surface where the developed interfacial area ratio is from 0.001 to 0.100 is formed. In a case where the supply of the cathode power and the supply of the substrate bias are stopped simultaneously, growth of the plurality of second crystal grains is suppressed, and thus the developed interfacial area ratio is likely to be less than 0.001.

Applications of the piezoelectric thin film device according to this embodiment are various. For example, the piezoelectric thin film device may be a piezoelectric microphone, a harvester, an oscillator, a resonator, an acoustic multilayer, or a filter. For example, the piezoelectric thin film device may be a piezoelectric actuator. The piezoelectric actuator may be used in haptics. That is, the piezoelectric actuator may be used in various devices for which a skin sensation feedback (haptic feedback) is required. For example, the devices for which the haptic feedback is required may be a wearable device, a touch pad, a display, or a game controller. For example, the piezoelectric actuator may be used in a head assembly, a head stack assembly, or a hard disk drive. For example, the piezoelectric actuator may be used in a printer head, or an inkjet printer device. The piezoelectric actuator may be used in a piezoelectric switch. For example, the piezoelectric thin film device may be a piezoelectric sensor or a piezoelectric transducer. For example, the piezoelectric sensor or the piezoelectric transducer may be used in a gyro sensor, a pressure sensor, a pulse wave sensor, an ultrasonic sensor, an ultrasonic transducer, or a shock sensor. The ultrasonic transducer may be a piezoelectric micromachined ultrasonic transducer (PMUT). A product using the piezoelectric micromachined ultrasonic transducer may be a biometric authentication sensor such as a fingerprint sensor and an ultrasonic blood vessel authentication sensor, a sensor for medical care or health care, or a time of flight (ToF) sensor. For example, the filter may be a bulk acoustic wave (BAW) filter or a surface acoustic wave (SAW) filter. Each of the above-described piezoelectric thin film devices may be a part or the entirety of micro electro mechanical system (MEMS).

The present disclosure is not limited to the above-described embodiment. Various modifications of the present disclosure can be made within a range not departing from the gist of the present disclosure, and the modification examples are also included in the present disclosure.

### EXAMPLES

The present disclosure will be described in detail with reference to the following examples and comparative examples. The present disclosure is not limited to the following examples.

### Example 1

As the substrate, a wafer consisting of a silicon single crystal was used. A diameter of the substrate was eight inches, and the thickness of the substrate was 725 μm. The thickness of the substrate was uniform. The main surface of the substrate was parallel to a (100) plane of Si.

The adhesive layer was formed directly on the entire main surface of the substrate by RF magnetron sputtering in a vacuum chamber. The adhesive layer consisted of aluminum nitride that does not contain an additive element. As a sputtering target, an elementary substance of Al was used. An atmosphere inside the vacuum chamber was a mixed gas of Ar and N₂. Input power per unit area of the sputtering target was 3.72 W/cm². A temperature of the substrate in the process of forming the adhesive layer was maintained at 300° C. The substrate bias was 30 W. The thickness of the adhesive layer was uniform. The thickness of the adhesive layer was adjusted to 30 nm.

The first electrode layer consisting of Mo was formed on the entire surface of the adhesive layer by RF magnetron sputtering within a vacuum chamber. As a sputtering target, an elementary substance of Mo was used. An atmosphere inside the vacuum chamber was an Ar gas. Input power per unit area of the sputtering target was 0.93 W/cm². A temperature of the substrate and the adhesive layer in the process of forming the first electrode layer was maintained at 600° C. The thickness of the first electrode layer was uniform. The thickness of the first electrode layer was adjusted to 0.2 μm.

The piezoelectric thin film was formed directly on the entire surface of the first electrode layer by RF magnetron sputtering in a vacuum chamber. As a sputtering target, a metal elementary substance of each of Al, Mg, and Zr was used. That is, three kinds of metal targets were used. An atmosphere inside the vacuum chamber was a mixed gas of Ar and N₂. Input power (cathode power) per unit area of each of the sputtering targets was 3.72 W/cm². A film formation pressure (atmospheric pressure inside the vacuum chamber) was 0.2 Pa. The substrate bias was 20 W. Supply of the substrate bias was stopped after further passage of 10 seconds from a point of time at which supply of the cathode power was stopped. The thickness of the piezoelectric thin film was adjusted to approximately 1000 nm.

A stacked body prepared by the above-described procedure consisted of the substrate, the adhesive layer stacked directly on the substrate, the first electrode layer stacked directly on the adhesive layer, and the piezoelectric thin film stacked directly on the first electrode layer.

### <Composition of Piezoelectric Thin Film>

The composition of the piezoelectric thin film was analyzed by X-ray fluorescence analysis (XRF). In the XRF, a wavelength dispersive fluorescent X-ray device (RIGAKU AZX-400, manufactured by Rigaku Corporation) was used. An analysis result showed that the piezoelectric thin film consists of aluminum nitride containing magnesium and zirconium. ([Mg]+[Zr])/([Al]+[Mg]+[Zr]) in the piezoelectric thin film is shown in the following Table 1. Definition of ([Mg]+[Zr])/([Al]+[Mg]+[Zr]) is as described above. In the following Table 1, ([Mg]+[Zr])/([Al]+[Mg]+[Zr]) is noted as “(Mg+Zr) ratio”. [Mg]/([Mg]+[Zr]) in the piezoelectric thin film is shown in the following Table 1. Definition of [Mg]/([Mg]+[Zr]) is as described above. In the following Tables 1 to 3, [Mg]/([Mg]+[Zr]) is noted as “Mg ratio”.

### <Crystal Structure of Piezoelectric Thin Film>

A crystal structure of the piezoelectric thin film was analyzed by an X-ray diffraction (XRD) method. In the XRD method, a multi-purpose X-ray diffraction device (SmartLab, manufactured by Rigaku Corporation) was used. 2θ-θ scan, ω scan, and 2θχ-ϕ scan using the X-ray diffraction device were performed on the surface of the piezoelectric thin film. Analysis results by the XRD method were as follows.

The piezoelectric thin film consisted of crystalline aluminum nitride having a wurtzite structure. The aluminum nitride contained the (0001) plane oriented parallel to a first main surface of the piezoelectric thin film (surface of the first electrode layer). The first electrode layer had a body-centered cubic structure. A (110) plane of the body-centered cubic structure was parallel to the first main surface of the piezoelectric thin film (surface of the first electrode layer).

### <Developed Interfacial Area Ratio Sdr>

The developed interfacial area ratio Sdr of a second main surface (exposed main surface) of the piezoelectric thin film was measured by an atomic force microscope (AFM). The developed interfacial area ratio Sdr was measured at three measurement regions randomly selected from the second main surface. Each measurement region was a square with a side length of 5 μm in a direction parallel to the first main surface of the piezoelectric thin film. An average value of the developed interfacial area ratio Sdr of the three measurement regions was calculated. Measurement of the developed interfacial area ratio Sdr was performed on the basis of International standard (ISO25178). As the atomic force microscope, Park XE-HDD manufactured by Park Systems Corporation was used. The average value of the developed interfacial area ratio Sdr is shown in the following Table 1.

### <Cross-Section of Piezoelectric Thin Film>

A cross-section of the piezoelectric thin film was observed by transmission electron microscope (TEM). As the TEM, Titan G2 manufactured by Thermo Fisher Scientific Inc. (formerly FEI company) was used. The cross-section observed by the TEM was orthogonal to the first main surface of the piezoelectric thin film (surface of the first electrode layer). An observation result on the cross-section of the piezoelectric thin film was as follows.

A plurality of first crystal grains (columnar crystals) grew approximately or completely orthogonally with respect to the first main surface of the piezoelectric thin film (surface of the first electrode layer). A plurality of second crystal grains grew obliquely with respect to the plurality of first crystal grains. Ends of the plurality of second crystal grains were exposed on the second main surface of the piezoelectric thin film. That is, each of a plurality of convex portions formed on the second main surface of the piezoelectric thin film consisted of the end of one or more second crystal grains.

An electron diffraction pattern was measured at each of a plurality of measurement points within the cross-section observed by the TEM. The electron diffraction pattern was also measured by the TEM. An electron diffraction pattern measured at any one of first crystal grains exposed on the cross-section contained a diffraction spot derived from the (0002) plane of the aluminum nitride in the first crystal grains. An electron diffraction pattern measured at any one of second crystal grains exposed on the cross-section contained not only a diffraction spot derived from the (0002) plane of the aluminum nitride in the first crystal grains, but also a diffraction spot derived from the (0002) plane of the aluminum nitride in the second crystal grains. That is, the (0002) plane (and (0001) plane) of the aluminum nitride in the second crystal grains was inclined with respect to the (0002) plane (and the (0001) plane) of the aluminum nitride in the first crystal grains. An angle α between a reference line L1 and a reference line L2 was measured in the electron diffraction pattern measured at the second crystal grains. Definitions of the reference line L1 and the reference line L2 are as described above. The angle θ between the (0001) plane of the aluminum nitride in the first crystal grains and the (0001) plane of the aluminum nitride in the second crystal grains was specified on the basis of the angle α. An average value of the angle θ specified at three measurement points is shown in the following Table 1.

### <Area Fraction and Heywood Diameter>

A secondary electron image of each of ten measurement regions in the second main surface of the piezoelectric thin film was taken by a scanning electron microscope (SEM). The ten measurement regions were randomly selected from the second main surface. As the SEM, S-4700 manufactured by Hitachi High-Tech Corporation was used. Each of the secondary electron images was parallel to the first main surface of the piezoelectric thin film. Each of the secondary electron images was rectangular, and dimensions of each of the secondary electron images was 12.8 μm (length)×9.01 μm (width). A monochrome image of each of the secondary electron images was obtained by image processing (binarization processing) of each of the secondary electron images. An area fraction RA of a plurality of second crystal grains in each of the monochrome images was measured. Definition of the area fraction RA is as described above. An average value of the area fraction RA measured at ten measurement regions is shown in the following Table 1. A Heywood diameter of each of the second crystal grains in each of the monochrome images was measured. Definition of the Heywood diameter is as described above. A maximum value and a minimum value of the Heywood diameter measured at ten measurement regions (secondary electron image) are shown in the following Table 1. The image processing of each of the secondary electron images, and the measurement of the area fraction RA and the Heywood diameter were performed by image analysis software. As the image analysis software, image analysis software (not for sale) manufactured by TDK Corporation was used.

<Piezoelectric Constant d₃₃>

A piezoelectric constant d₃₃ (unit: pC/N) of the piezoelectric thin film was measured. Details of measurement of the piezoelectric constant d₃₃ were as follows. An average value of the piezoelectric constant d₃₃ measured at three points is shown in the following Table 1.
Measurement device: d₃₃ meter (PM200) manufactured by Piezotest Pte Ltd.
Frequency: 110 Hz
Clamp pressure: 0.25 N

### <Peeling-Off Rate of Second Electrode Layer>

A peeling-off rate of the second electrode layer was measured by a cross hatch test. The cross hatch test was a method complying with Japanese Industrial Standard K 5600 May 6:1999 (ISO 2409:1992).

The second electrode layer consisting of silver was formed on the entire second main surface of the piezoelectric thin film by sputtering. The thickness of the second electrode layer was approximately uniform. The thickness of the second electrode layer was adjusted to 60 μm. In the cross hatch test, a plurality of cross hatch cuts orthogonal to each other were formed on the surface of the second electrode layer to divide the second electrode layer into 1000 lattices (squares). An interval of the cross hatch cuts was 1 mm. After forming the lattices, an adhesive tape was stuck on the entire surface of the second electrode layer. After peeling off the adhesive tape from the surface of the second electrode layer, the number n of lattices in which at least a part of the second electrode layer was peeled-off from the second main surface of the piezoelectric thin film was counted. A total number of lattices formed on the surface of the second electrode layer is expressed as N, and a peeling-off rate of the second electrode layer is defined as (n/N)×100. The peeling-off rate is shown in the following Table 1.

### Examples 2 to 18, and Comparative Examples 1 and 2

In a process of forming a piezoelectric thin film of each of Examples 2 to 18, and Comparative Examples 1 and 2, the input power (cathode power) per unit area of each sputtering target was changed. The substrate bias (power) was not supplied in the process of forming the piezoelectric thin film of Comparative Example 1. That is, the substrate bias in the process of forming the piezoelectric thin film of Comparative Example 1 was 0 W. The substrate bias in the process of forming the piezoelectric thin film of Comparative Example 2 was 20 W. Supply of the substrate bias of Comparative Example 2 was stopped at a point of time after further passage of 60 seconds from a point of time at which supply of the cathode power was stopped.

In the process of forming the piezoelectric thin film of each of Examples 12 to 16, a target consisting of a metal elementary substance of Hf was used instead of a target consisting of a metal elementary substance of Zr.

In the process of forming the piezoelectric thin film of each of Examples 17 and 18, a target consisting of a metal elementary substance of Sc was used instead of the target consisting of the metal elementary substance of Zr. In the process of forming the piezoelectric thin film of each of Examples 17 and 18, a target consisting of a metal elementary substance of Mg was not used.

A piezoelectric thin film of each of Examples 2 to 18 and Comparative Examples 1 and 2 was prepared by the same method as in Example 1 except for the above-described matters. Analysis and measurement relating to the piezoelectric thin film of each of Examples 2 to 18, and Comparative Examples 1 and 2 were performed by the same method as in Example 1. Results of the analysis and the measurement relating to the piezoelectric thin film of each of Examples 2 to 18 and Comparative Examples 1 and 2 are shown in the following Tables 1 to 3.

In the following Table 2, ([Mg]+[Et])/([Al]+[Mg]+[Et]) is noted as “(Mg+Et) ratio”.

In the following Table 3, [Sc]/([Al]+[Sc]) is noted as “Sc ratio”.

The piezoelectric thin film of each of Examples 2 to 11 and Comparative Examples 1 and 2 consisted of aluminum nitride containing magnesium and zirconium.

The piezoelectric thin film of each of Examples 12 to 16 consisted of aluminum nitride containing magnesium and hafnium.

The piezoelectric thin film of each of Examples 17 and 18 consisted of aluminum nitride containing scandium.

The piezoelectric thin film of each of Examples 2 to 18 and Comparative Examples 1 and 2 consisted of crystalline aluminum nitride having a wurtzite structure.

The aluminum nitride of each of Examples 2 to 18 and Comparative Examples 1 and 2 contained the (0001) plane oriented in parallel to the first main surface of the piezoelectric thin film (surface of the first electrode layer).

In any case of Examples 2 to 18 and Comparative Examples 1 and 2, a plurality of first crystal grains (columnar crystals) grew approximately or completely orthogonally with respect to the first main surface of the piezoelectric thin film (surface of the first electrode layer).

In any case of Examples 2 to 18 and Comparative Example 2, a plurality of second crystal grains grew obliquely with respect to the plurality of first crystal grains. On the other hand, in a case of Comparative Example 1, the plurality of second crystal grains were not detected.

In any case of Examples 2 to 18 and Comparative Example 2, ends of the plurality of second crystal grains were exposed on the second main surface of the piezoelectric thin film. That is, even in any case of Examples 2 to 18 and Comparative Example 2, each of a plurality of convex portions formed on the second main surface of the piezoelectric thin film consisted of the end of one or more second crystal grains.

TABLE 1

| | (Mg + Zr) | Mg | | | | | Heywood diameter (nm) | | | |
|---|---|---|---|---|---|---|---|---|---|---|
| | ratio | ratio | Sdr | | θ | Area | Maximum | Minimum | Peeling- | d₃₃ |
| Table 1 | (—) | (—) | (%) | (—) | (°) | fraction | value | value | off rate | (pC/N) |
| Example 1 | 0.42 | 0.40 | 0.1 | 0.001 | 0.05 | 0.005% | 10 | 5 | 3.1% | 12.0 |
| Example 2 | 0.43 | 0.56 | 10.0 | 0.100 | 32 | 25.0% | 2000 | 5 | 2.8% | 12.0 |
| Example 3 | 0.41 | 0.47 | 0.2 | 0.002 | 0.1 | 0.007% | 10 | 5 | 1.3% | 14.0 |
| Example 4 | 0.43 | 0.46 | 5.5 | 0.055 | 30 | 22.0% | 2000 | 5 | 1.2% | 14.0 |
| Example 5 | 0.44 | 0.42 | 0.4 | 0.004 | 0.4 | 0.01% | 10 | 5 | 0.8% | 15.0 |
| Example 6 | 0.40 | 0.41 | 4.3 | 0.043 | 17 | 20.0% | 2000 | 5 | 0.7% | 15.0 |
| Example 7 | 0.41 | 0.46 | 2.3 | 0.023 | 13 | 3.6% | 10 | 5 | 0.2% | 17.4 |
| Comparative | 0.40 | 0.45 | 0.0 | 0.000 | — | 0.0% | 0 | 0 | 20.0% | 13.5 |
| Example 1 | | | | | | | | | | |
| Comparative | 0.43 | 0.56 | 11.9 | 0.119 | 12 | 40.0% | 2000 | 5 | 18.0% | 8.2 |
| Example 2 | | | | | | | | | | |

TABLE 2

| | | (Mg + Et) | Mg | | | | | Heywood diameter (nm) | | | |
|---|---|---|---|---|---|---|---|---|---|---|---|
| | | ratio | ratio | Sdr | | θ | Area | Maximum | Minimum | Peeling- | d₃₃ |
| Table 2 | Et | (—) | (—) | (%) | (—) | (°) | fraction | value | value | off rate | (pC/N) |
| Example 8 | Zr | 0.03 | 0.25 | 0.1 | 0.001 | 0.05 | 0.005% | 10 | 5 | 1.8% | 10.0 |
| Example 9 | Zr | 0.10 | 0.45 | 0.2 | 0.002 | 0.1 | 0.01% | 10 | 5 | 2.0% | 11.5 |
| Example 10 | Zr | 0.36 | 0.45 | 9.5 | 0.095 | 30 | 20.0% | 2000 | 5 | 0.8% | 14.3 |
| Example 11 | Zr | 0.60 | 0.60 | 10.0 | 0.100 | 32 | 25.0% | 2000 | 5 | 1.0% | 11.0 |
| Example 12 | Hf | 0.03 | 0.26 | 0.2 | 0.002 | 0.1 | 0.0% | 11 | 5 | 1.7% | 10.1 |
| Example 13 | Hf | 0.59 | 0.58 | 9.8 | 0.098 | 31 | 23.5% | 2000 | 5 | 0.9% | 11.4 |
| Example 14 | Hf | 0.09 | 0.45 | 0.3 | 0.003 | 0.09 | 0.0% | 10 | 5 | 1.9% | 10.6 |
| Example 15 | Hf | 0.35 | 0.45 | 9.0 | 0.090 | 28 | 19.2% | 1900 | 5 | 1.0% | 14.0 |
| Example 16 | Hf | 0.44 | 0.41 | 4.1 | 0.041 | 18 | 21.1% | 2000 | 5 | 0.8% | 14.9 |

TABLE 3

| | Sc | | | | | Heywood diameter (nm) | | | |
|---|---|---|---|---|---|---|---|---|---|
| | ratio | Sdr | | θ | Area | Maximum | Minimum | Peeling- | d₃₃ |
| Table 3 | (—) | (%) | (—) | (°) | fraction | value | value | off rate | (pC/N) |
| Example 17 | 0.10 | 0.1 | 0.001 | 0.05 | 0.005% | 10 | 5 | 1.8% | 15.0 |
| Example 18 | 0.40 | 10.0 | 0.100 | 32 | 25.0% | 2000 | 5 | 1.0% | 28.0 |

FIG. 7A is a secondary electron image of a part of the second main surface of the piezoelectric thin film of Example 7, and was measured by the SEM. The secondary electron image shown in FIG. 7A is parallel to the first main surface. FIG. 7B is a monochrome image obtained by image processing (binarization processing) of the secondary electron image shown in FIG. 7A.

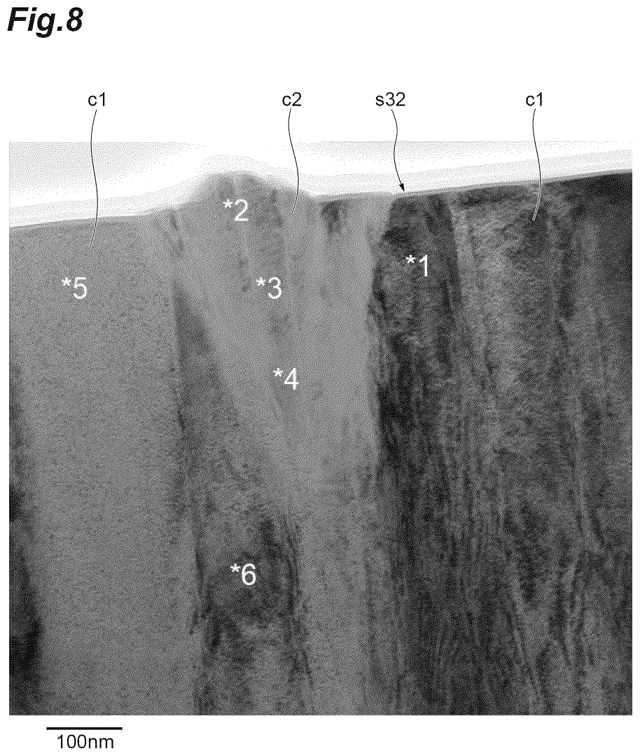

FIG. 8 is an image of a cross-section of the piezoelectric thin film of Example 7, and was measured by the TEM. The cross-section shown in FIG. 8 is orthogonal to the first main surface of the piezoelectric thin film. Six asterisks (*) in FIG. 8 are Measurement Points 1 to 6. FIG. 8 shows that an end of the second crystal grain c2 is exposed on the second main surface s32 as a convex portion.

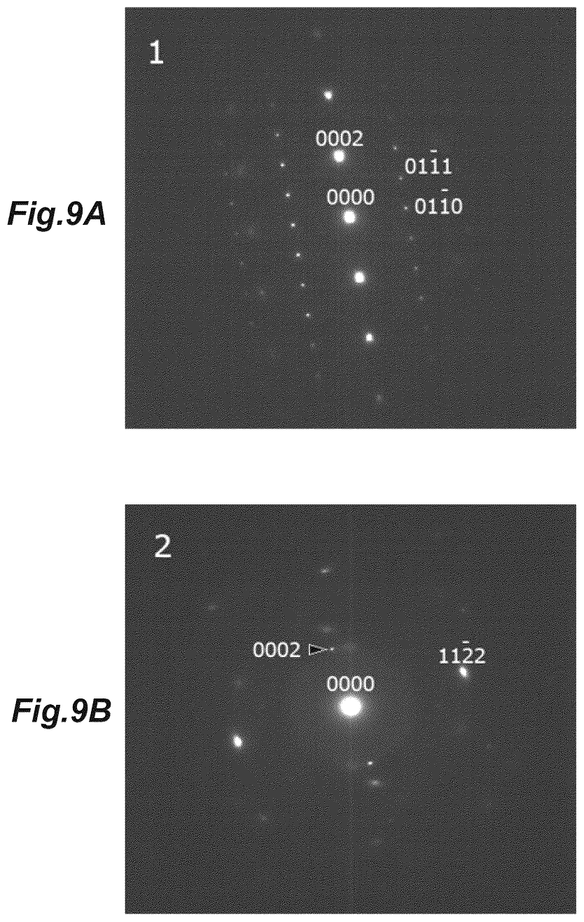

FIG. 9A is an electron diffraction pattern measured by causing an electron beam to be incident to Measurement Point 1 (first crystal grain) in the cross-section shown in FIG. 8.

FIG. 9B is an electron diffraction pattern measured by causing an electron beam to be incident to Measurement Point 2 in the cross-section shown in FIG. 8.

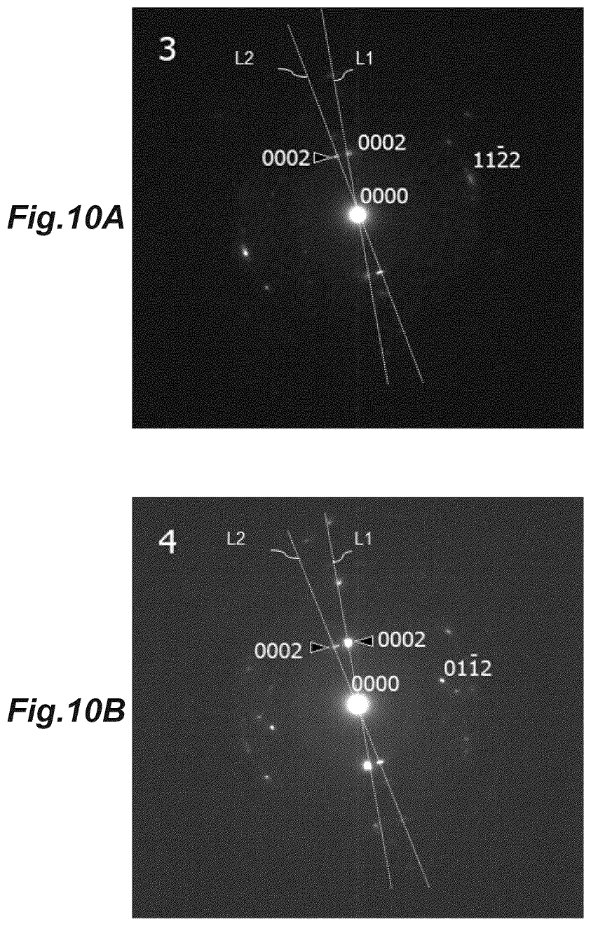

FIG. 10A is an electron diffraction pattern measured by causing an electron beam to be incident to Measurement Point 3 (second crystal grain) in the cross-section shown in FIG. 8. An angle between a reference line L1 and a reference line L2 in FIG. 10A was 11°.

FIG. 10B is an electron diffraction pattern measured by causing an electron beam to be incident to Measurement Point 4 (second crystal grain) in the cross-section shown in FIG. 8. An angle between a reference line L1 and a reference line L2 in FIG. 10B was 12°.

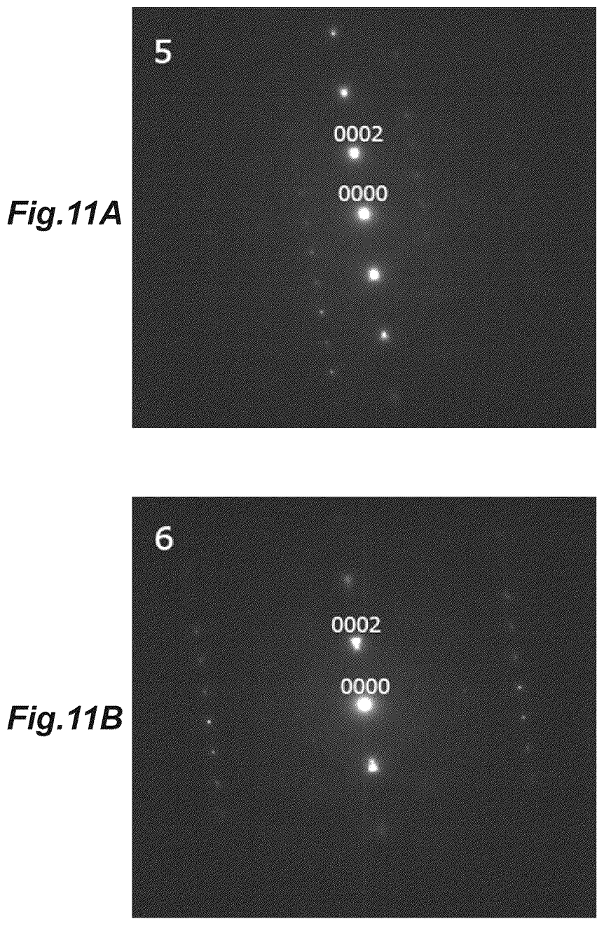

FIG. 11A is an electron diffraction pattern measured by causing an electron beam to be incident to Measurement Point 5 (first crystal grain) in the cross-section shown in FIG. 8.

FIG. 11B is an electron diffraction pattern measured by causing an electron beam to be incident to Measurement Point 6 (first crystal grain) in the cross-section shown in FIG. 8.

In each electron diffraction pattern of Example 7, four numerical values attached to each diffraction spot are indexes indicating a direction of a lattice plane from which each diffraction spot is derived.

### INDUSTRIAL APPLICABILITY

For example, the piezoelectric thin film according to an aspect of the present disclosure may be used in microphones, sensors, transducers, filters, harvesters, or actuators.

### REFERENCE SIGNS LIST

1: first electrode layer, 2: second electrode layer, 3: piezoelectric thin film, 10: piezoelectric thin film device, s1: surface of first electrode layer, s2: surface of second electrode layer, s31: first main surface of piezoelectric thin film, s32: second main surface of piezoelectric thin film, c1: first crystal grain, c2: second crystal grain, uc: unit cell of aluminum nitride (wurtzite structure), θ: angle between (0001) plane of aluminum nitride in first crystal grains and (0001) plane of aluminum nitride in second crystal grains, Ed: divalent element, Etr: trivalent element, Et: tetravalent element.

What is claimed is:

1. A piezoelectric thin film having a first main surface, and a second main surface located on a rear side of the first main surface,
wherein the piezoelectric thin film contains crystalline aluminum nitride having a wurtzite structure,
the aluminum nitride contains a divalent element and a tetravalent element, or the aluminum nitride contains a trivalent element, and
a developed interfacial area ratio of the second main surface is from 0.001 to 0.100.

2. The piezoelectric thin film according to claim 1, further containing:
a plurality of first crystal grains and a plurality of second crystal grains,
wherein both the first crystal grains and the second crystal grains contain the aluminum nitride,
a (0001) plane of the aluminum nitride in the first crystal grains is parallel to the first main surface,
a (0001) plane of the aluminum nitride in the second crystal grains is inclined to the (0001) plane of the aluminum nitride in the first crystal grains, and
the plurality of second crystal grains are exposed on the second main surface.

3. A piezoelectric thin film having a first main surface, and a second main surface located on a rear side of the first main surface,
wherein the piezoelectric thin film contains a plurality of first crystal grains and a plurality of second crystal grains,
both the first crystal grains and the second crystal grains contain crystalline aluminum nitride having a wurtzite structure,
a (0001) plane of the aluminum nitride in the first crystal grains is parallel to the first main surface,
a (0001) plane of the aluminum nitride in the second crystal grains is inclined to the (0001) plane of the aluminum nitride in the first crystal grains,
the plurality of second crystal grains are exposed on the second main surface, and
a developed interfacial area ratio of the second main surface is from 0.001 to 0.100.

4. The piezoelectric thin film according to claim 2,
wherein an angle between the (0001) plane of the aluminum nitride in the first crystal grains and the (0001) plane of the aluminum nitride in the second crystal grains is from 0.1° to 30°.

5. The piezoelectric thin film according to claim 2,
wherein a secondary electron image of the second main surface is taken by a scanning electron microscope,
the secondary electron image is parallel to the first main surface, and
a ratio of a total area of the plurality of second crystal grains in the secondary electron image is from 0.01% to 20%.

6. The piezoelectric thin film according to claim 2,
wherein a secondary electron image of the second main surface is taken by a scanning electron microscope,
the secondary electron image is parallel to the first main surface, and
a Heywood diameter of the second crystal grains which is measured on the secondary electron image is from 5 nm to 2000 nm.

7. A piezoelectric thin film device, comprising:
the piezoelectric thin film according to claim 1;
a first electrode layer; and
a second electrode layer,
wherein the first main surface is directly stacked on the first electrode layer, and
the second electrode layer is directly stacked on the second main surface.

8. The piezoelectric thin film according to claim 3,
wherein an angle between the (0001) plane of the aluminum nitride in the first crystal grains and the (0001) plane of the aluminum nitride in the second crystal grains is from 0.1° to 30°.

9. The piezoelectric thin film according to claim 3,
wherein a secondary electron image of the second main surface is taken by a scanning electron microscope,
the secondary electron image is parallel to the first main surface, and
a ratio of a total area of the plurality of second crystal grains in the secondary electron image is from 0.01% to 20%.

10. The piezoelectric thin film according to claim 3,
wherein a secondary electron image of the second main surface is taken by a scanning electron microscope,
the secondary electron image is parallel to the first main surface, and
a Heywood diameter of the second crystal grains which is measured on the secondary electron image is from 5 nm to 2000 nm.

11. A piezoelectric thin film device, comprising:
the piezoelectric thin film according to claim 3;
a first electrode layer; and
a second electrode layer,
wherein the first main surface is directly stacked on the first electrode layer, and
the second electrode layer is directly stacked on the second main surface.
